(19) United States
(12) Patent Application Publication
(10) Pub. No.: US 2015/0373874 A1
(43) Pub. Date: Dec. 24, 2015

(54) SYSTEMS AND METHODS FOR EXHAUSTING GAS FROM ENCLOSURES

(71) Applicant: Emerson Network Power, Energy Systems, North America, Inc., Warrenville, IL (US)

(72) Inventors: Brant David KINNEY, Lagrange, GA (US); Virendra NIRMALKAR, Jagdalpur (IN); Vinayak Dattatraya BHAT, Dombivli (IN)

(21) Appl. No.: 14/743,718

(22) Filed: Jun. 18, 2015

(30) Foreign Application Priority Data
Jun. 18, 2014 (IN) 1964/MUM/2014

(51) Int. Cl. H05K 7/20; F25B 21/02

(52) U.S. Cl. CPC H05K 7/20154; F25B 21/02

(57) ABSTRACT

An enclosure configured to house one or more components capable of releasing undesirable gas includes a plurality of walls defining at least two chambers. One of the chambers is configured to house one or more components capable of releasing undesirable gas. The enclosure further includes one or more temperature regulating devices and a heat exchanger assembly. The heat exchanger assembly includes a heat exchanger and at least one fan in fluid communication with the heat exchanger and said one of the chambers. The at least one fan is configured to create a negative pressure in the enclosure for drawing external air into the enclosure, drawing the external air and the undesirable gas released by the one or more components of said one of the chambers into the heat exchanger assembly, and exhausting the external air and the undesirable gas from the enclosure. Other example enclosures are also disclosed.

### CROSS-REFERENCE TO RELATED APPLICATION

This application claims the benefit of Indian Application No. 1964/MUM/2014 filed Jun. 18, 2014. The entire disclosure of the above application is incorporated herein by reference.

### FIELD

The present disclosure relates to systems and methods for exhausting gas from enclosures.

### BACKGROUND

This section provides background information related to the present disclosure which is not necessarily prior art.

Enclosures commonly house components that generate and/or release undesirable gas. This undesirable gas may be flammable and/or explosive under certain circumstances. For example, batteries may release hydrogen gas during a recharging process. In some cases, hydrogen gas may ignite and/or cause an explosion if concentration of the gas rises above about four percent. As such, the enclosures typically include a vent to exhaust hydrogen gas and/or other undesirable gases.

### SUMMARY

This section provides a general summary of the disclosure, and is not a comprehensive disclosure of its full scope or all of its features.

According to one aspect of the present disclosure, an enclosure configured to house one or more components capable of releasing undesirable gas includes a plurality of walls defining at least two chambers. One of the chambers includes an opening configured to allow external air to enter the enclosure. The one chamber is configured to house one or more components capable of releasing undesirable gas. The enclosure further includes one or more temperature regulating devices configured to regulate a temperature in the one chamber and a heat exchanger assembly adjacent one of the at least two chambers. The heat exchanger assembly defines an opening, and includes a heat exchanger and at least one fan in fluid communication with the heat exchanger and the one chamber. The at least one fan of the heat exchanger assembly is configured to create a negative pressure in the enclosure for drawing external air into the enclosure via the opening of the one chamber, drawing the external air and the undesirable gas released by the one or more components of the one chamber into the heat exchanger assembly, and exhausting the external air and the undesirable gas from the enclosure via the opening in the heat exchanger assembly.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram of an enclosure including a fan for creating negative pressure to exhaust one or more undesirable gases in the enclosure according to one example embodiment of the present disclosure.

FIG. 2 is a block diagram of an enclosure including a heat exchanger assembly having a fan for creating negative pressure to exhaust one or more undesirable gases in the enclosure according to another example embodiment.

FIG. 3 is a front view of an enclosure including multiple chambers, a door in an open position, and a heat exchanger assembly for creating negative pressure to exhaust one or more undesirable gases in the enclosure according to yet another example embodiment.

FIG. 4 is a portion of the enclosure of FIG. 3 including flow paths of air and hydrogen gas.

FIG. 5A is side view of the enclosure of FIG. 3 with the door closed.

FIG. 5B is an enlarged view of the encircled portion of FIG. 5A.

FIG. 5C is an enlarged isometric view of a portion of the door of FIG. 3.

FIG. 5D is an isometric view of the heat exchanger assembly and the door of FIG. 3.

FIG. 6A is an isometric view of the enclosure of FIG. 3 with the door closed.

FIG. 6B is an isometric view of the enclosure of FIG. 3 with the door open.

FIG. 6C is a top view of the enclosure of FIG. 3 with the door open.

Corresponding reference numerals indicate corresponding parts or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

As disclosed herein, undesirable gas may be exhausted from enclosures by various methods. For example, one method includes exhausting air including undesirable gas such as hydrogen gas, etc. from an enclosure by creating negative pressure in the enclosure with a fan. In some example embodiments, the fan may be a component of a heat exchanger assembly.

Due to the negative pressure created by a fan, air (e.g., ambient air) external the enclosure is drawn into the enclosure. This negative pressure forces the external air and hydrogen gas (if present in the enclosure) through the fan (and sometimes through a heat exchanger assembly). After passing through the fan, the air and hydrogen gas may be exhausted from the enclosure.

By creating negative pressure in the enclosure (and in some cases in the heat exchanger assembly), hydrogen gas (and/or other undesirable gases) in the enclosure may be removed. As such, the concentration of hydrogen gas (and/or other undesirable gases) within the enclosure may remain at a suitable level (e.g., below about four percent, etc.), be reduced to a suitable level, etc. Thus, the chance of explosions and/or other harmful events may be reduced without compromising the enclosure and its components.

Additionally, other features may assist in exhausting air including hydrogen gas from an enclosure. For example, the density of hydrogen gas and other undesirable gases is typically lower than the density of air. Thus, these gases may rise relative to the more dense air and naturally flow towards one or more vents (e.g., openings, etc.) in an enclosure as further explained below. As such, the physical characteristics of the gases may assist in exhausting these gases from the enclosure.

The methods disclosed herein may be employed in a wide variety of enclosures including, for example, enclosures deployed indoors and/or outdoors (e.g., Outside Plant (OSP) enclosures, etc.). The enclosures may be any suitable enclosure housing components (e.g., one or more rechargeable batteries as explained below, etc.) capable of releasing hydrogen gas and/or another undesirable gas. For example, the enclosures may house only batteries, house batteries and one or more other components including, for example, rectifiers, converters, control circuits, etc. In some examples, the enclosures may be employed in telecommunication applications and thus may need to meet particular requirements related to, for example, hydrogen gas concentrations, etc.

Additionally or alternatively, the enclosure may be a sealed enclosure (e.g., an environmental sealed enclosure). If appropriate, the sealed enclosure may include gaskets, seals, potting, filters, etc. adjacent vent openings to protect the interior of the enclosure from contaminants (e.g., moisture, dirt, air, dust, etc.). In some examples, a sealed enclosure may reduce power required to thermally regulate an interior of the enclosure.

Additionally or alternatively, the enclosure may be temperature controlled. For example, the enclosure may include one or more controllable fans, vents, heat dissipating components, etc. to ensure the temperature within the enclosure is maintained at a defined temperature.

In some cases, an air flow path through the enclosure as further explained below may help maintain the internal temperature of the enclosure at a defined temperature. Thus, the air flow path may assist in temperature control in addition to or in place of the one or more controllable fans, vents, heat dissipating components, etc.

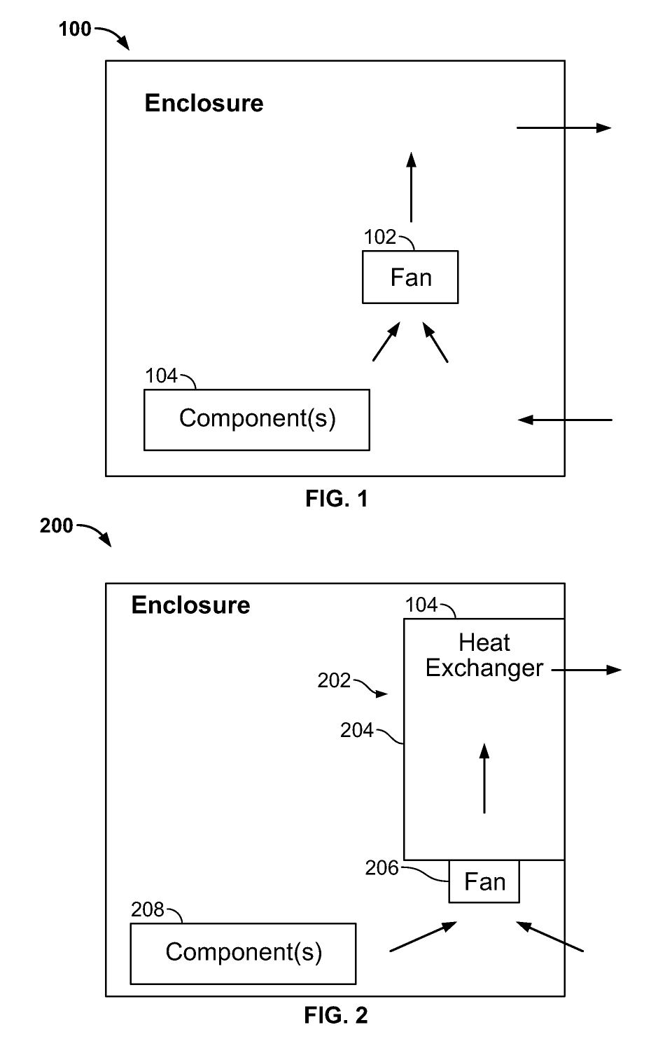

Some example enclosures are described below with reference to FIGS. 1-6. It should be understood, however, that the teachings of this disclosure are not limited to the particular examples shown in FIGS. 1-6, and can be applied to a wide variety of other enclosures or the like.

An enclosure according to one example embodiment of the present disclosure is illustrated in FIG. 1 and indicated generally by reference number 100. As shown in FIG. 1, the enclosure 100 includes a fan 102 and component(s) 104 capable of releasing hydrogen gas and/or another undesirable gas. As explained above, the fan 102 creates negative pressure in the enclosure 100.

By creating the negative pressure in the enclosure 100, air (e.g., ambient air) external the enclosure is drawn into the enclosure 100. The external air and the undesirable gas (released by the component(s) 104) pass through the fan 102 and exhaust from the enclosure 100 as explained above. The airflow path (e.g., including the external air and the undesirable gas) are represented by arrows shown in FIG. 1.

In some examples, the enclosure 100 includes a wall defining one or more perforations (e.g., opening(s), etc.) or the like. In such cases, the external air may be drawn into the enclosure 100 and/or the mixture of air and undesirable gas may be exhausted from the enclosure 100 via the perforations. Additionally, one or more filters and/or damper(s) may be employed to substantially prevent solid and/or liquid contaminates from entering the enclosures 100 via the perforations.

Additionally or alternatively, the component(s) 104 may be housed in a chamber or the like to provide isolation from other equipment, etc. in the enclosure 100 as further explained below. This is commonly referred to as a sealed chamber. The sealed chamber may include a wall defining one or more perforations to allow the undesirable gas generated by the component(s) 104 to exit and pass through the fan 102.

FIG. 2 illustrates another example enclosure 200 including a heat exchanger assembly 202 and one or more components 208 capable of releasing hydrogen gas and/or another undesirable gas. The heat exchanger assembly 202 includes a heat exchanger 204 and a fan 206 in fluid communication with the heat exchanger 204. As explained above, the fan 206 may create a negative pressure in the heat exchanger assembly 202 thereby drawing air external the enclosure 200 and the hydrogen gas released by the component(s) 208 into the heat exchanger assembly 202, and exhausting the mixture from the enclosure 200 via the heat exchanger assembly 202.

Additionally, the heat exchanger 204 may be operable to transfer heat generated by one or more heat generating components into the air flow path of the exhausting air and hydrogen gas. For example, the heat generating components may include one or more of the components 208 and/or other components (not shown) such as rectifiers, converters, etc. Thus, the heat exchanger assembly 202 may assist in regulating temperature in the enclosure 200 and/or exhausting air including hydrogen gas (and/or another undesirable gas) from the enclosure 200 as explained above.

In some embodiments, the enclosure 200 may include one or more vents for allowing air, hydrogen gas, etc. to pass as explained above with reference to FIG. 1.

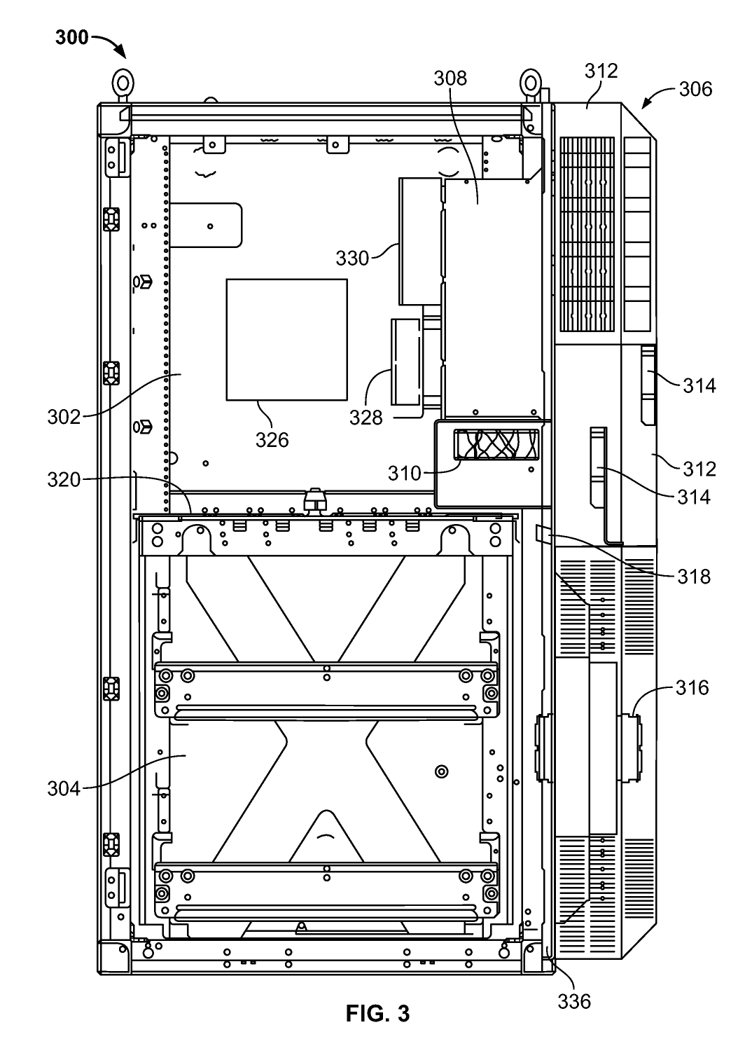

FIGS. 3-6 illustrates another example enclosure 300 including an equipment chamber 302, a battery chamber 304, and a heat exchanger assembly 306 adjacent the equipment chamber 302. The equipment chamber 302 may house one or more electrical components 326 including, for example, rectifiers, converters, control circuits, etc. The battery chamber 304 may house one or more rechargeable batteries and/or other components capable of releasing undesirable gas such as hydrogen gas, etc. as explained above. As shown in FIG. 3, the equipment chamber 302 is positioned adjacent the battery chamber 304. More particularly, the battery chamber 304 is positioned below the equipment chamber 302. Although the enclosure 300 of FIG. 3 includes two chambers, it should be apparent to those skilled in the art that the enclosure 300 may include additional and/or alternative chambers if desired.

The enclosure 300 includes various walls defining the equipment chamber 302 and the battery chamber 304. In some embodiments, one or more of the walls defining the equipment chamber 302 and/or one or more of the walls defining the battery chamber 304 may be exterior wall(s) of the enclosure. Alternatively, one or more of the walls of the equipment chamber 302 and/or one or more of the battery chamber 304 may be within (e.g., at least partially enclosed, etc.) the enclosure 300.

In some examples, the wall(s) of the battery chamber 304 and/or the wall(s) of the equipment chamber 302 may define a barrier 320 between the battery chamber 304 and the equipment chamber 302. In this way, the battery chamber 304 and the equipment chamber 302 may be isolated from each other.

In some embodiments, the heat exchanger assembly 306 may be sealed such that fluid communication is substantially restricted between the heat exchanger assembly 306 and the equipment chamber 302. Thus, the heat exchanger assembly 306 may be isolated from the equipment chamber 302 to substantially prevent liquid, air, etc. from passing from the heat exchanger assembly 306 to the equipment chamber 302.

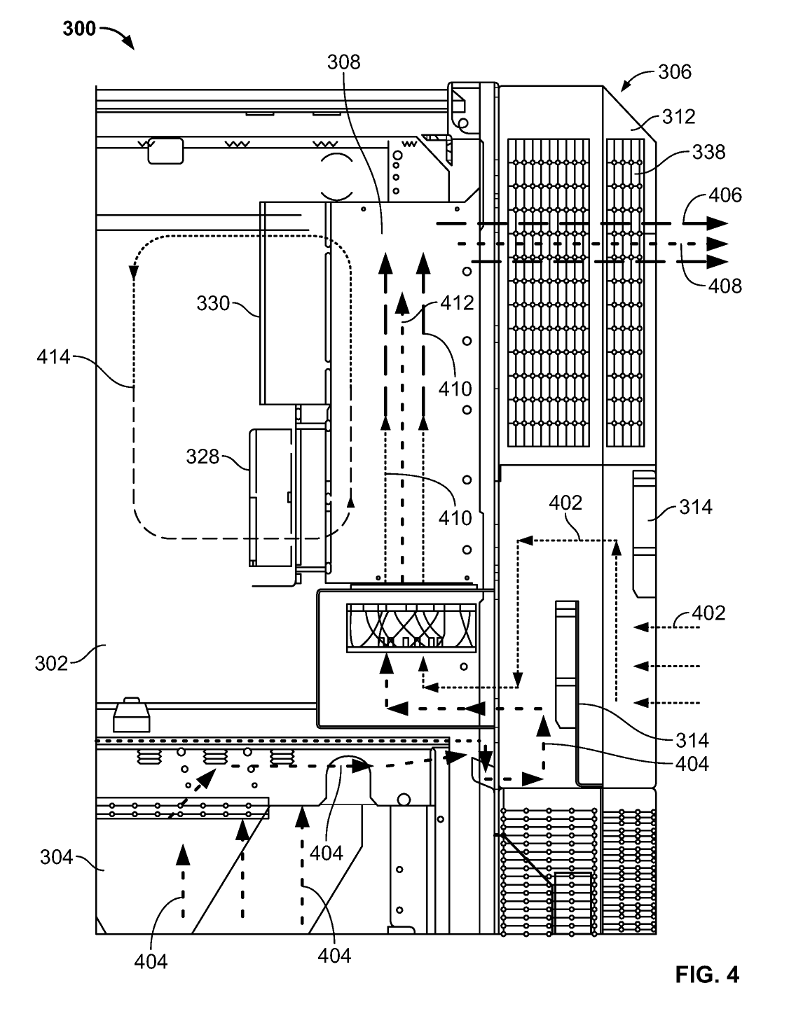

As shown in FIGS. 3 and 4, the heat exchanger assembly 306 includes a heat exchanger 308, a fan 310 in fluid communication with the heat exchanger 308 and the battery chamber 304, and a heat exchanger shroud 312 positioned adjacent the heat exchanger 308 and the fan 310. As explained above, the fan 310 creates a negative pressure in the heat exchanger assembly 306 to force air (e.g., air from the battery chamber 304, air external the heat exchanger assembly 306, air external the enclosure 300, etc.) and hydrogen gas released from the batteries in the battery chamber 304 into the heat exchanger assembly 306. By employing the fan 310 of the heat exchanger assembly 306 to create this negative pressure, thermal performance of the enclosure 300 may be substantially unaffected.

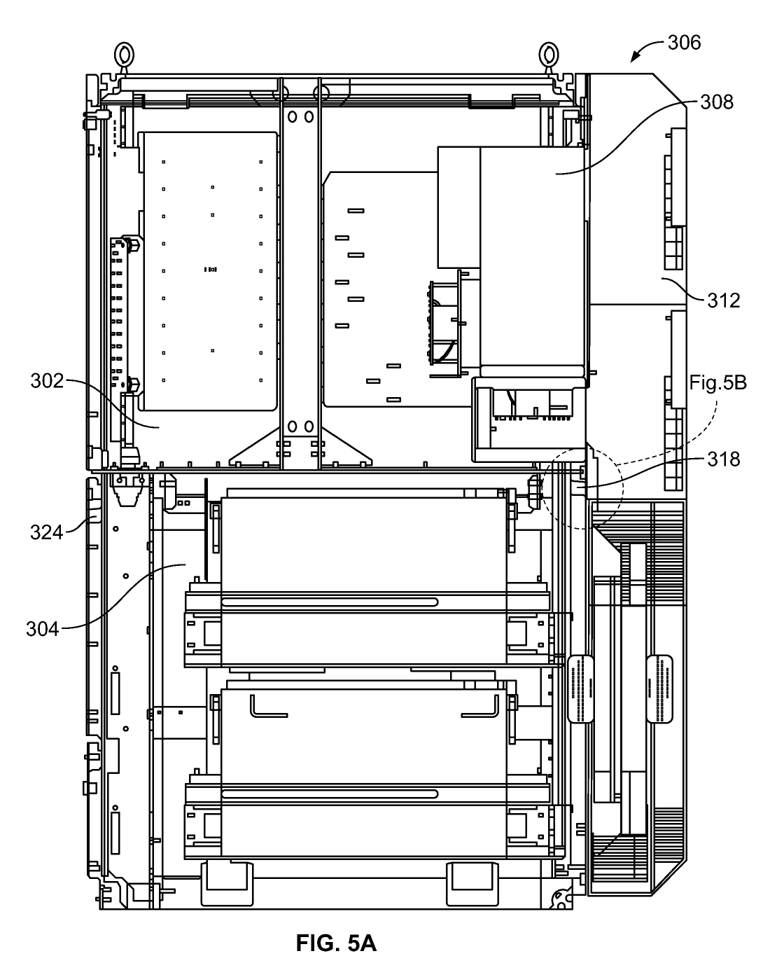

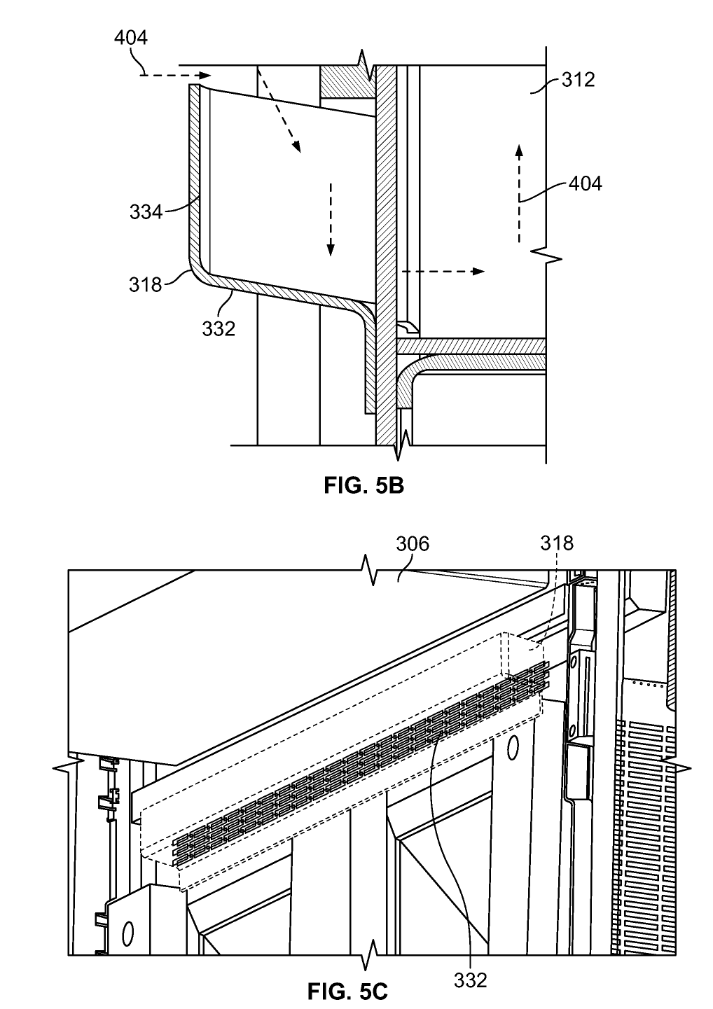

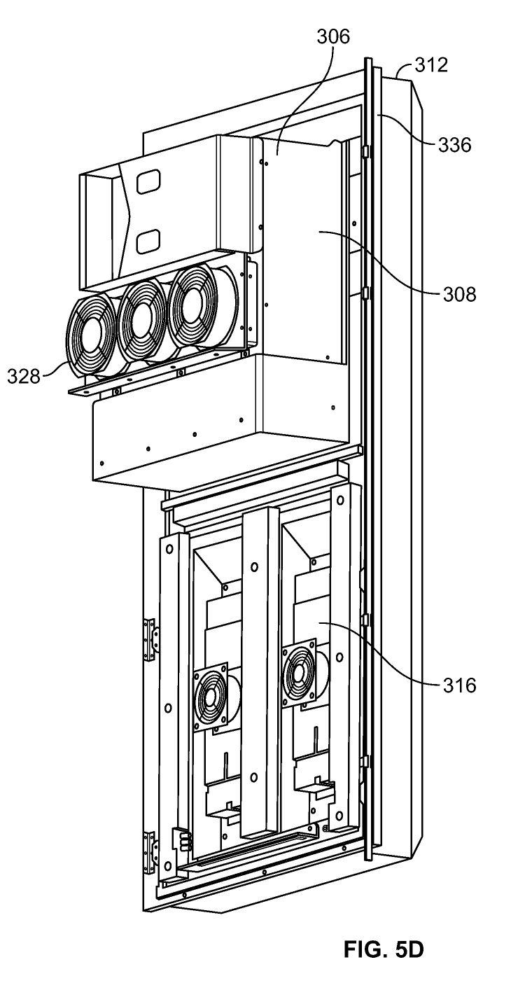

In some embodiments, and as shown in FIG. 4, various air/gas flow paths are created in the enclosure 300 from the negative pressure. For example, arrows 402 represent air flowing from outside the enclosure 300 and into the heat exchanger assembly 306 through one or more vents 340 (e.g., one or more openings, etc.) in the heat exchanger shroud 312. In particular, external air flows through one or more vents in the heat exchanger shroud 312, through the fan 310 and into the heat exchanger 308. Arrows 404 represent a mixture of air and hydrogen gas flowing from the battery chamber 304 into the heat exchanger assembly 306. In particular, air/hydrogen gas flows through one or more vents (e.g., perforations 322 of FIG. 5C) of the enclosure 300, into the heat exchanger shroud 312, through the fan 310 and into the heat exchanger 308.

As the mixture of air and/or hydrogen gas flows through the heat exchanger 308, the temperature of the mixture increases due to heat transferring from the equipment chamber 302 to the heat exchanger 308. For example, the heat exchanger assembly 306 may include one or more fans 328 adjacent the heat exchanger 308 for circulating air within the equipment chamber 302. This circulating air may help transfer heat from within the equipment chamber 302 to the airflow path of the air and/or hydrogen gas mixture via one or more heat sinks 330 and/or another suitable heating transferring devices, etc. of the heat exchanger 308. This transfer of heat is represented by a heat transfer loop 414 (e.g., an inner loop) between the equipment chamber 302 and the heat exchanger 308. Arrow 410 and arrow 412 represent the heated air and hydrogen gas, respectively.

Arrow 406 and arrow 408 represent the heated air and hydrogen gas, respectively, exhausting from the enclosure 300. In particular, the heated air/hydrogen gas flows through one or more vents 338 (e.g., one or more openings, etc.) in the heat exchanger shroud 312 and exhausts into the surrounding environment. In some embodiments, air flowing from outside the enclosure 300 (e.g., arrows 402), through the heat exchanger assembly 306 (e.g., arrows 410), and then exhausting from the enclosure 300 (e.g., arrows 406) represents an outer loop.

Referring back to FIG. 3, the temperature in the battery chamber 304 may be regulated at a desired level. In some examples, the temperature adjacent the batteries may be preferably below about 30 degrees Celsius (about 86 degrees Fahrenheit), at about 23 degrees Celsius (about 75 degrees Fahrenheit), etc.

For example, to regulate the temperature in the battery chamber 304, the enclosure 300 includes one or more thermoelectric modules 316 positioned below the heat exchanger assembly 306 and adjacent the battery chamber 304, and one or more heaters (not shown) positioned adjacent a bottom portion of the battery chamber 304. The thermoelectric modules 316 may be housed in, covered by, etc. a thermoelectric module shroud. Although the enclosure 300 of FIG. 3 includes thermoelectric modules and heaters for regulating the temperature in the battery chamber 304, it should be apparent the enclosure 300 may include other suitable temperature regulating devices in addition to and/or alternative to the thermoelectric modules and/or heaters.

The thermoelectric modules 316 of FIG. 3 may be any suitable thermoelectric module including, for example, a thermoelectric cooler (e.g., a Peltier cooler, etc.), etc. In the example embodiment of FIG. 3, the thermoelectric modules 316 include two thermoelectric coolers (TECs). Alternatively, more or less TECs and/or other suitable thermoelectric modules may be employed.

Additionally, the heat exchanger assembly 306 may include noise dampers 314 positioned in the heat exchanger shroud 312. The noise dampers 314 substantially dampen the noise from the fan 310 exiting the enclosure 300. For example, the noise dampers 314 may include particular material(s) (e.g., metal, foam, etc.) to ensure the noise level is below 65 dB at a distance of five feet from the enclosure 300. Although two noise dampers 314 are shown in FIG. 3, it should be apparent that more or less noise dampers may be employed.

Additionally, the noise dampers 314 may restrict (at least to an extent) liquid and/or other contaminates (e.g., debris, etc.) from entering the enclosure 300. For example, the noise dampers 314 may substantially restrict wind driven rain from penetrating the heat exchanger shroud 312.

Additionally, the enclosure 300 may include one or more structures for preventing liquid and/or other contaminates from entering the battery chamber 304 via the vent 322. For example, as shown in FIGS. 3 and 5, the enclosure 300 includes a flange 318 extending a desired length between the heat exchanger assembly 306 and the thermoelectric modules 316. As shown best in FIG. 5B, the flange 318 includes various walls. For example, the various walls may include a substantially horizontal portion 332 extending from the heat exchanger assembly 306 and a substantially vertical portion 334 extending from the substantially horizontal portion 332. The substantially horizontal portion 332 is positioned below the opening 322 of the heat exchanger assembly. Additionally, one or more walls may be positioned adjacent end portions of the portions 332, 334 to form a bucket like shape when the flange 318 is mounted to the enclosure 300.

The flange 318 may restrict liquid (e.g., wind driven rain, etc.) from passing into the battery chamber, force liquid to flow back into the heat exchanger shroud 312, and divert the air/hydrogen gas exiting the battery chamber 304 (represented by arrows 404 as explained above). For example, and as shown best in FIG. 5B, the substantially horizontal portion 332 may be sloped such that liquid that passes through the opening(s) 322 and is blocked from entering the battery chamber 304 may flow back into the heat exchanger shroud 312. As shown in FIGS. 3-5, the flange 318 and the vent 322 are positioned below the barrier between the battery chamber 304 and the equipment chamber 302 as explained above. This ensures sufficient isolation between the battery chamber 304 and the equipment chamber 302, and between the equipment chamber 302 and the heat exchanger assembly 306 while still maintaining on negative pressure to extract air/hydrogen gas from the battery chamber 304 and into the heat exchanger assembly 306 as explained above.

Additionally, the enclosure 300 may include additional venting mechanisms. For example, and as shown in FIG. 5A, the enclosure 300 includes a vent 324 including, for example, one or more perforations or the like. In particular, a wall of the enclosure 300 and/or a wall of the battery chamber 304 may define the perforations. The vent 324 (sometimes referred to as an opening) may allow air to flow into the battery chamber 304 and out of the vent 322 as explained above.

Additionally, one or more filters and/or damper(s) may be employed to substantially prevent solid and/or liquid contaminates from entering the enclosures 300 via the vents (e.g. openings 322, 324, etc.).

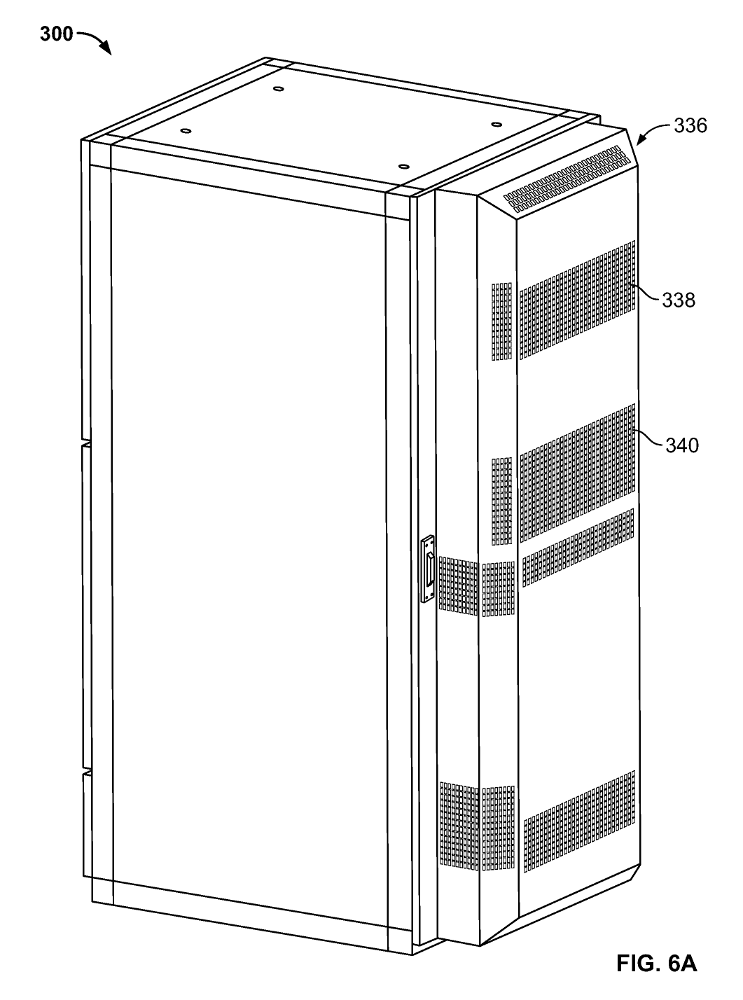

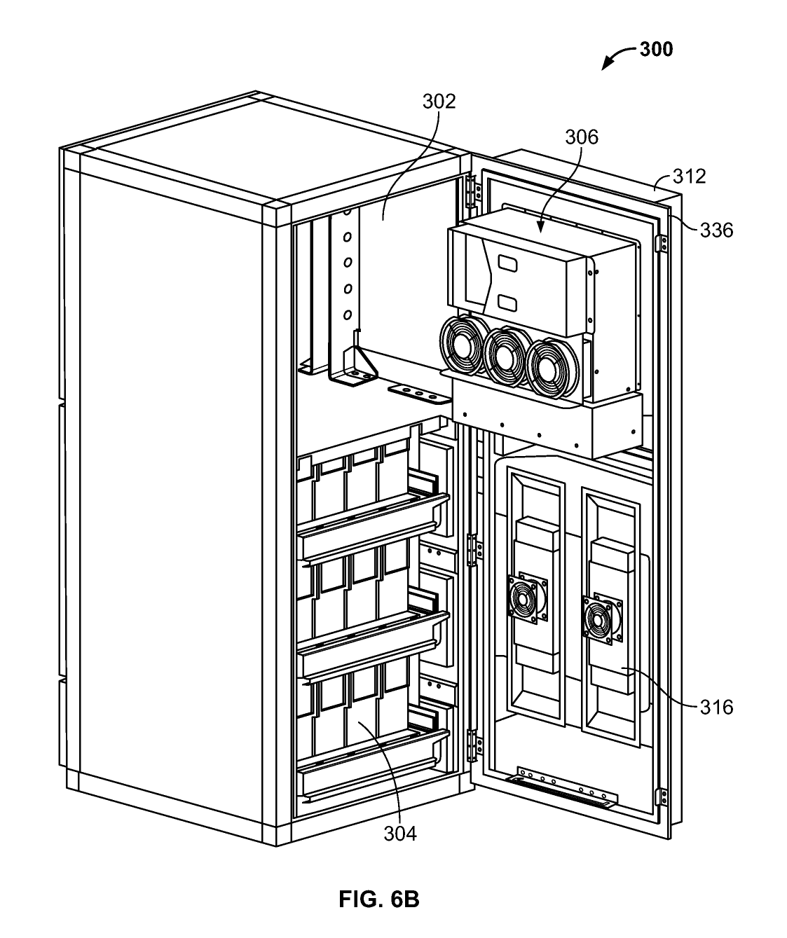

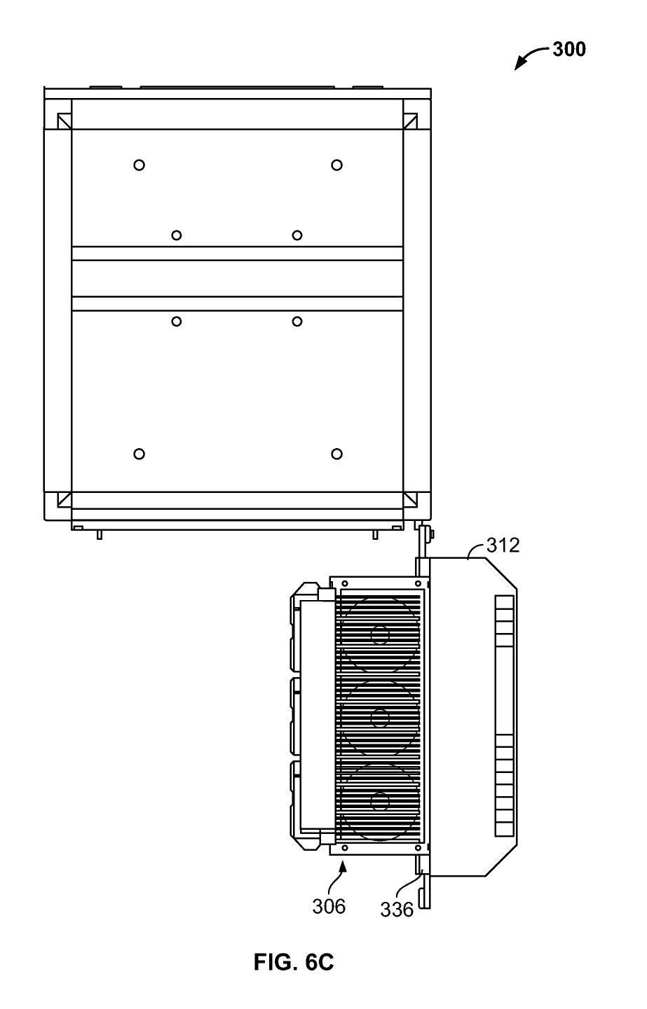

As shown best in FIGS. 5D, 6A, 6B and 6C, the enclosure 300 includes a door 336 for supporting the heat exchanger assembly 306 and the thermoelectric modules 316. As such, the heat exchanger assembly 306 may be considered a door mounted heat exchanger.

For example, and shown best in FIG. 5D, the heat exchanger assembly 306 (e.g., including its heat exchanger 308, fans 310, 328, heat exchanger shroud 312, etc.), and the thermoelectric modules 316 may be coupled to the door 336. In particular, the heat exchanger shroud 312 is coupled to an exterior facing side of the door 336 and the heat exchanger 308, fans 310, 328, and the thermoelectric modules 316 are coupled to an interior facing side of the door 336. Alternatively, the heat exchanger assembly 306 and/or the thermoelectric modules 316 may be positioned on another suitable side of the door and/or wall(s) of the enclosure 300 without departing from the scope of the present disclosure.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An enclosure configured to house one or more components capable of releasing undesirable gas, the enclosure comprising:
a plurality of walls defining at least two chambers, one of the chambers including an opening configured to allow external air to enter the enclosure, said one chamber configured to house one or more components capable of releasing undesirable gas;
one or more temperature regulating devices configured to regulate a temperature in said one chamber; and
a heat exchanger assembly adjacent one of the at least two chambers, the heat exchanger assembly defining an opening and including a heat exchanger and at least one fan in fluid communication with the heat exchanger and said one chamber, the at least one fan of the heat exchanger assembly configured to create a negative pressure in the enclosure for drawing external air into the enclosure via the opening of said one chamber, drawing the external air and the undesirable gas released by the one or more components of said one chamber into the heat exchanger assembly, and exhausting the external air and the undesirable gas from the enclosure via the opening in the heat exchanger assembly.

2. The enclosure of claim 1 wherein the one or more temperature regulating devices are adjacent said one chamber.

3. The enclosure of claim 2 wherein the one or more temperature regulating devices include at least one thermoelectric module.

4. The enclosure of claim 1 wherein the undesirable gas includes hydrogen gas.

5. The enclosure of claim 1 wherein the heat exchanger assembly defines another opening adjacent said one chamber for allowing the external air and the undesirable gas to enter the heat exchanger assembly.

6. The enclosure of claim 5 further comprising a structure adjacent said other opening, the structure configured to substantially prevent liquid and/or other contaminates from entering said one chamber.

7. The enclosure of claim 6 wherein the structure includes a flange having a substantially horizontal portion extending from the heat exchanger assembly below said other opening and a substantially vertical portion extending from the substantially horizontal portion.

8. The enclosure of claim 1 wherein the at least two chambers include an equipment chamber configured to house one or more electrical components and wherein the heat exchanger assembly is adjacent the equipment chamber.

9. The enclosure of claim 1 wherein the enclosure includes a door and wherein the heat exchanger assembly is coupled to the door.

10. The enclosure of claim 9 wherein the door includes an interior facing side and an exterior facing side opposing the interior facing side, wherein the heat exchanger assembly includes a heat exchanger shroud coupled to the exterior facing side of the door, and wherein the fan of the heat exchanger assembly is coupled to the interior facing side of the door.

11. The enclosure of claim 9 wherein the one or more temperature regulating devices is coupled to the door.

12. The enclosure of claim 1 wherein the enclosure is a sealed enclosure.

13. The enclosure of claim 1 wherein the at least two chambers include an equipment chamber configured to house one or more electrical components and wherein the equipment chamber is isolated from said one chamber.

14. The enclosure of claim 1 further comprising one or more components positioned in said one chamber, the one or more components capable of releasing the undesirable gas.

15. The enclosure of claim 14 wherein the one or more components capable of releasing the undesirable gas include at least one rechargeable battery.

16. The enclosure of claim 14 wherein the at least two chambers include an equipment chamber, the enclosure further comprising one or more electrical components positioned in the equipment chamber.
